(19) United States
(12) Patent Application Publication
(10) Pub. No.: US 2023/0098095 A1
(43) Pub. Date: Mar. 30, 2023

(54) PHOTODIODE BASED ON STANNOUS SELENIDE SULFIDE NANOSHEET/GaAs HETEROJUNCTION AND PREPARATION METHOD AND USE THEREOF

(71) Applicant: South China Normal University, Guangzhou City (CN)

(72) Inventors: Wei GAO, Guangzhou City (CN); Ying HUANG, Guangzhou City (CN); Mengmeng YANG, Guangzhou City (CN); Jingbo LI, Guangzhou City (CN)

(21) Appl. No.: 17/889,703

(22) Filed: Aug. 17, 2022

(30) Foreign Application Priority Data
Sep. 17, 2021 (CN) 202111093985 .3

(51) Int. Cl. H01L 31/109; H01L 31/0232; H01L 31/0296; H01L 31/0304; H01L 31/0352; H01L 31/0224; H01L 31/18

(52) U.S. Cl. CPC H01L 31/109; H01L 31/18; H01L 31/0304; H01L 31/02325; H01L 31/02966; H01L 31/022408; H01L 31/035209

(57) ABSTRACT

The present disclosure provides a photodiode based on a stannous selenide sulfide nanosheet/GaAs heterojunction and a preparation method and use thereof. The photodiode comprises a structure of the stannous selenide sulfide nanosheet/GaAs heterojunction, forming Au electrodes through thermal vapor deposition on the stannous selenide sulfide nanosheet and GaAs, respectively, and conducting an annealing treatment in a protective gas at a temperature in a range of 150-250° C. The heterojunction is formed by transferring the stannous selenide sulfide nanosheet to a GaAs window, and the GaAs window is obtained by depositing a medium layer film on GaAs and etching the medium layer through lithography and an etchant.

### CROSS-REFERENCE TO RELATED APPLICATIONS

This patent application claims the benefit and priority of the Chinese Pat. Application No. 202111093985.3 filed on Sep. 17, 2021. The entire disclosure of the above application is incorporated herein by reference.

### FIELD

The present disclosure belongs to the technical field of mixed-dimensional van der Waals heterojunctions, and in particular relates to a photodiode based on a stannous selenide sulfide nanosheet/GaAs heterojunction and a preparation method and use thereof.

### INTRODUCTION

GaAs belongs to the second-generation N-type semiconductor materials of group III-V compounds, has a direct band gap of 1.42 eV and high electron mobility, and is very suitable for forming light-emitting diodes, photovoltaic cells and near-infrared photodetectors with high performances. However, the high surface density of state of GaAs greatly reduces the light on/off ratio and photoresponsivity of photodetectors. Since the discovery of graphene, two-dimensional (2D) materials with unique photoelectric properties have attracted extensive attention. Due to the structural advantages of no surface dangling-bonds, no need for lattice matching and generally weak van der Waals interactions of the 2D materials, random assembling and stacking may be allowed to generate various types of van der Waals heterojunctions. In post-Moore era, research based on the mixed-dimensional heterojunctions of two-dimensional materials/three-dimensional materials has greatly promoted the integration technology development of 3D semiconductors such as Si and GaAs, and has become one of the hottest researching frontiers in the fields of material science and condensed matter physics. For example, Dhyani et al. have verified that a molybdenum disulfide/Si device has a photoresponsivity of 8.75 A/W and a fast response time of 10 µs. Meanwhile, Wu et al. have found that a molybdenum disulfide/GaAs device is improved in light absorption coefficient, thereby greatly improving specific detectivity under zero bias.

In the 2D material system of the post-transition metal chalcogenide (PTMC), stannous sulfide and stannous selenide are layered nano-materials with a band gap in a range of 0.7-1.55 eV, and are P-type semiconductor materials with great advantages such as low cost, non-toxicity and abundant yield. Among them, the α-phase crystal structure with excellent thermal stability is an orthorhombic crystal system, which has obvious in-plane anisotropy especially in optics and electricity. According to theoretical speculation, the light absorption coefficient and the carrier mobility of stannous sulfide in the visible-infrared range may reach 5 × 10⁴ cm⁻¹ and 7.35 × 10⁴ cm²V⁻¹s⁻¹, respectively. Stannous selenide also shows an ultra-high light absorption coefficient (about 1 × 10⁵ cm⁻¹) and a relatively high thermoelectric ZT factor. The characteristics as above indicate that these two binary compounds have great application prospects in the fields of thermoelectric conversion, ferroelectric conversion, polarization imaging, solar photovoltaic cell and flexible devices. However, due to the strong interlayer force, considerable deep-level defects and strong electric field shielding effect between layers, the materials above have the problems such as difficulty in mechanical peeling, slow photoresponse, mediocre current on/off properties and limited light absorption efficiency, seriously hindering the development of these materials.

In recent years, alloy engineering has been an important research mean that may not only effectively control the band structures and the optical and electrical properties of semiconductors, but also suppress the deep-level defects in binary compounds. For example, Tan et al. have found that stannous selenide sulfide has a higher carrier mobility and better thermodynamic stability. In addition, Padha et al. have reported that a stannous selenide sulfide alloy (with a mass ratio of sulfur to selenium of 2:3) is significantly improved in light absorption coefficient (>10⁵ cm⁻¹). Chong et al. have studied the polarization properties of stannous selenide sulfide by using Raman spectroscopy and have found that the polarization behavior of stannous selenide sulfide is closely related to excitation wavelength. The research team of the inventor has made some achievements in preparation, anisotropy and photoelectric devices of stannous selenide sulfide single-crystal nanosheets. Despite the great progress in exploring the preparation, anisotropy and photoelectric devices of stannous selenide sulfide in recent years, there is still a long way to go to achieve the photodetectors with high performances. At present, the mixed-dimensional P-N heterojunctions of P-type stannous selenide sulfide/N-type GaAs have not been reported yet. The combination of the two may form a built-in electric field which is expected to realize self-driven broad-spectrum photoelectronic functions and polarization imaging functions, thus promoting the research and development of GaAs integration technologies.

### SUMMARY

In order to overcome the above deficiencies and shortcomings in the prior art, an objective of the present disclosure is to provide a photodiode based on a stannous selenide sulfide nanosheet/GaAs heterojunction.

Another objective of the present disclosure is to provide a method for preparing the above photodiode based on a stannous selenide sulfide nanosheet/GaAs heterojunction.

A yet another objective of the present disclosure is to provide use of the above photodiode based on a stannous selenide sulfide nanosheet/GaAs heterojunction.

The objectives of the present disclosure are achieved by the following technical solutions:

A photodiode based on a stannous selenide sulfide nanosheet/GaAs heterojunction, wherein the photodiode comprises a structure of the stannous selenide sulfide nanosheet/GaAs heterojunction, obtained by overlapping a stannous selenide sulfide nanosheet and GaAs, forming Au electrodes through thermal vapor deposition on the stannous selenide sulfide nanosheet and GaAs, respectively, and conducting an annealing treatment in a protective gas at a temperature in a range of 150-250° C.

In some embodiments, the Au electrode has a thickness of 20-500 nm; the protective gas is nitrogen or argon; the annealing treatment is conducted for 15-120 min; the stannous selenide sulfide nanosheet has a lateral dimension of 10-100 µm and a thickness of 5-100 nm.

In some embodiments, the photodiode comprises a photodiode based on a lateral stannous selenide sulfide nanosheet/GaAs heterojunction and a photodiode based on a vertical stannous selenide sulfide nanosheet/GaAs heterojunction; in the photodiode based on a lateral stannous selenide sulfide nanosheet/GaAs heterojunction, the Au electrodes are formed through thermal vapor deposition on the stannous selenide sulfide nanosheet and GaAs, respectively; in the photodiode based on a vertical stannous selenide sulfide nanosheet/ GaAs heterojunction, the Au electrodes are formed through thermal vapor deposition on the stannous selenide sulfide nanosheet and a back of GaAs, respectively.

A method for preparing the photodiode based on a stannous selenide sulfide nanosheet/GaAs heterojunction, comprising:

S1, cleaning an N-type GaAs substrate with acetone, isopropanol and deionized water in sequence and drying with a nitrogen gun, and depositing a medium layer film on the N-type GaAs substrate by atomic layer deposition or plasma enhanced chemical vapor deposition;

S2, photoetching and developing a window on the medium layer film by using ultraviolet lithography, and placing in an etchant to completely etch an exposed medium layer window to obtain a GaAs window;

S3, spin-coating a surface of a stannous selenide sulfide nanosheet/substrate with a soluble polymer solution, and heating and solidifying at a temperature in a range of 100-150° C. to obtain a polymer film/stannous selenide sulfide nanosheet/substrate;

S4, immersing the polymer film/stannous selenide sulfide nanosheet/substrate in a treatment solution, then aligning the polymer film/stannous selenide sulfide nanosheet separated from the substrate with the GaAs window obtained in step S2, and heating at a temperature in a range of 100-150° C. to make the stannous selenide sulfide nanosheet contact with the GaAs window to form a van der Waals heterojunction, so as to obtain a polymer film/stannous selenide sulfide nanosheet/GaAs substrate; and

S5, heating the polymer film/stannous selenide sulfide nanosheet/GaAs substrate in acetone at 70° C., then transferring to a fresh acetone solution for immersion, and cleaning to remove the polymer film; forming Au electrodes through thermal vapor deposition on the stannous selenide sulfide nanosheet and the GaAs window, respectively, and then conducting an annealing treatment in a protective gas at a temperature in a range of 150-250° C. to obtain the photodiode based on a stannous selenide sulfide nanosheet/GaAs heterojunction.

In some embodiments, in step S1, the medium layer film is of SiO₂, Al₂O₃ or HfO₂, and has a thickness of 12-300 nm.

In some embodiments, in step S2, the etchant comprises an aqueous hydrofluoric acid solution and an aqueous ammonium fluoride solution; a volume ratio of the aqueous hydrofluoric acid solution to the aqueous ammonium fluoride solution is in a range of (1-4):(6-24); a volume concentration of the aqueous hydrofluoric acid solution is in a range of 40-49%, and a volume concentration of the aqueous ammonium fluoride solution is in a range of 30-40%.

In some embodiments, in step S3, the stannous selenide sulfide nanosheet has a lateral dimension of 10-100 µm and a thickness of 5-100 nm; the substrate is of SiO₂/Si, mica or sapphire.

In some embodiments, in step S3, the soluble polymer solution is an anisole solution of polymethyl methacrylate or a toluene solution of polystyrene with a mass percentage of 8-10 wt.%; the spin-coating is conducted at a speed in a range of 3,000-7,000 rpm for 30-120 S; the heating is conducted for 15-45 min.

In step S3, the conditions for preparing a stannous selenide sulfide single-crystal nanosheet by physical vapor deposition (PVD) of the stannous selenide sulfide are as follows: placing a precursor on a quartz boat, which is performed by mixing stannous sulfide and stannous selenide high-purity powders in a predetermined proportion, placing a SiO₂/Si wafer surface-treated with oxygen plasma above the quartz boat with a polished side down, with a pressure of 10⁻³ \-10 Torr, a heating rate of 20° C./min, a growth temperature in a range of 750-800° C., under an atmosphere selected from the group consisting of nitrogen and argon, and with a gas flow of 2-10 sccm. When the growth temperature reaches 750-800° C., the quartz boat is moved to the center of a heating zone by moving a quartz tube for holding for 2-4 min, and the quartz tube is moved to move the quartz boat out of the heating zone. After cooling at room temperature, a large number of flake samples are observed with the help of an optical microscope. The stannous selenide sulfide nanosheet has a thickness of 5-200 nm and a lateral dimension of 10-100 µm.

In some embodiments, in step S4, the heating is conducted for 5-20 min; in step S5, the heating is conducted for 7-15 min, the immersion is conducted for 10 min-12 h, and the cleaning is conducted with solvents of isopropanol, anhydrous ethanol and deionized water successively.

Use of the photodiode based on a stannous selenide sulfide nanosheet/GaAs heterojunction in the field of photovoltaic devices or self-driven polarization-sensitive photodetectors is provided.

Compared with the prior art, the present disclosure has the following benefits:
1. According to the photodiode based on a stannous selenide sulfide nanosheet/GaAs heterojunction of the present disclosure, different proportions of stannous selenide sulfide nanosheets, stannous sulfide and stannous selenide binary compounds are prepared by PVD, and a P-N structure is constructed by a wet transfer method and the GaAs for self-driven polarization-sensitive photodetection. Different proportions of stannous selenide sulfide nanosheets and GaAs can form type-II band alignment, and the electric field direction is from N-type GaAs to P-type stannous selenide sulfide. Under the irradiation of visible-near-infrared light, a large number of electron-hole pairs are generated in a depletion region of the stannous selenide sulfide nanosheet/GaAs heterojunction, and can be rapidly separated under zero bias and negative bias, thus achieving high-performance photoelectric detection. In the present disclosure, alloy engineering and the van der Waals construction technology are combined to solve the scientific problems such as stannous selenide sulfide alloy, large noise current of GaAs, limited light absorption efficiency and adverse effect of a high surface density of state of GaAs.
2. In the present disclosure, the stannous selenide sulfide alloy prepared by PVD can control the light absorption coefficient and the response wavelength range, and at the same time, can effectively suppress the deep energy level defects of stannous sulfide and stannous selenide, and reduce the non-radiative recombination lifetime of the carrier and shorten the photoresponse time.
3. In the present disclosure, the photodiode based on a stannous selenide sulfide nanosheet (an element mass ratio of sulfur to selenium is 1:1)/GaAs heterojunction has a wide spectral response (405-1,064 nm) and self-driven photoelectric performance (under 405 nm laser irradiation, its maximum photoresponsivity reaches 10.2 A· W⁻¹, the maximum specific detectivity reaches 4.8× 10¹² Jones, and the rise and fall times are 0.5/3.47 ms). In addition, the stannous selenide sulfide nanosheet/GaAs heterojunction has dichroic ratios of 1.25 at 405 nm and 1.45 at 635 nm, and a remarkable polarized photocurrent can be obtained, which shows good potential for use in self-driven polarization-sensitive photodetectors at specific wavelengths.

### DRAWINGS

FIG. 1 is an optical microscope image of the lateral stannous selenide sulfide nanosheet/GaAs heterojunction prepared according to Example 1.

FIG. 2 is a current-voltage graph of the photodiode based on the lateral stannous selenide sulfide nanosheet/GaAs heterojunction of Example 1.

FIG. 3 is a current-voltage graph of the photodiode based on the lateral stannous selenide sulfide nanosheet/GaAs heterojunction of Example 1 at different incident wavelengths.

FIG. 4 is a current-time graph of the photodiode based on the lateral stannous selenide sulfide nanosheet/GaAs heterojunction of Example 1 at different wavelengths.

FIG. 5 is a graph showing the self-driven response time of the photodiode based on the lateral stannous selenide sulfide nanosheet/GaAs heterojunction of Example 1 under 405 nm laser light.

FIG. 6 is a graph showing the normalized photoresponsivity of the photodiode based on the lateral stannous selenide sulfide nanosheet/GaAs heterojunction of Example 1 at different incident wavelengths and a bias voltage of 0 V.

FIG. 7 is a graph showing the relationship between the photoresponsivity-photocurrent and light power density of the photodiode based on the lateral stannous selenide sulfide nanosheet/GaAs heterojunction of Example 1 under 405 nm incident light and a bias voltage of 0 V.

FIG. 8 is a graph showing the relationship between the external quantum efficiency-specific detectivity and light power density of the photodiode based on the lateral stannous selenide sulfide nanosheet/GaAs heterojunction of Example 1 under 405 nm incident light and a bias voltage of 0 V.

FIG. 9 is a schematic diagram of a three-dimensional structure of the photodiode based on the lateral stannous selenide sulfide nanosheet/GaAs heterojunction of Example 1 under irradiation of polarized light.

FIG. 10 is a normalized photocurrent-angle polar plot of the photodiode based on the lateral stannous selenide sulfide nanosheet/GaAs heterojunction of Example 1 under 405 nm incident light.

FIG. 11 is a normalized photocurrent-angle polar plot of the photodiode based on the lateral stannous selenide sulfide nanosheet/GaAs heterojunction of Example 1 under 635 nm incident light.

FIG. 12 is a current-voltage curve of the photodiode based on a vertical stannous selenide sulfide nanosheet/GaAs heterojunction of Example 3.

### DETAILED DESCRIPTION

The technical solutions in the examples of the present disclosure will be described below clearly and completely with reference to the drawings in the present disclosure, which should not be construed as limiting the protection scope of the present disclosure. All other examples obtained by those ordinary skilled in the art based on the examples of the present disclosure without creative efforts should fall within the protection scope of the present disclosure. The experimental methods described in the following examples are conventional methods unless otherwise specified; and the reagents and equipment can be obtained from commercial sources unless otherwise specified. The present disclosure will be further described in detail below.

### Example 1

Step 1. A 2-inch Si-doped N-type GaAs substrate was cut into a size of 1 cm × 1 cm, and ultrasonically cleaned with acetone, isopropanol and deionized water in sequence for 5-10 min to obtain a clean GaAs substrate. A SiO₂ film with a thickness of 300 nm was deposited on the GaAs substrate at 300° C. by PECVD (Plasma Enhanced Chemical Vapor Deposition).

Step 2. A 1 mm × 1 mm window was developed on the substrate with a maskless UV lithography machine, and then placed in a plastic beaker containing an etchant (the etchant was a mixture of 20 mL of an aqueous hydrofluoric acid solution with a volume concentration of 49% and 120 mL of an aqueous ammonium fluoride solution with a volume concentration of 40%) for etching for 1 min to expose the GaAs surface, and immersed in acetone and deionized water successively to obtain an etched GaAs window.

Step3. A stannous selenide sulfide nanosheet was prepared by PVD as the following steps: stannous sulfide and stannous selenide powders were compounded according to a mass ratio of 1:1, uniformly shaken well through a centrifugal tube, and slowly transferred to a quartz boat. A 1 cm × 1 cm SiO₂/Si wafer surface-treated with O₂ plasma was placed above the quartz boat with a polished side down. The above steps were performed with a pressure of 10⁻³ \-10 Torr, a heating rate of 20° C./min, under an atmosphere selected from the group consisting of nitrogen and argon, and with a gas flow of 2-10 sccm, preferably 5 sccm. When the temperature reached 750-800° C., the quartz boat was moved to the center of a heating zone by moving a quartz tube for holding for 2-4 min, and the quartz tube was moved to move the quartz boat out of the heating zone. After cooling at room temperature, a large number of dark green flake samples were observed with a microscope. The stannous selenide sulfide single-crystal nanosheet had a thickness of 5-200 nm and a lateral dimension of 10-100 µm. The stannous selenide sulfide alloy nanosheet with a thickness of about 22 nm was selected for subsequent transfer.

Step 4. A PMMA-anisole film was formed by spin-coating with an 8 wt.% PMMA anisole solution on the stannous selenide sulfide nanosheet with a spin coater at 4000 rpm for 1 min. After spin-coating two times, the spin-coated product was heated on a heating plate at 150° C. for 30 min to remove the anisole solvent, and then the stannous selenide sulfide nanosheet/PMMA was transferred to a buffered oxide etchant (BOE) for immersion and etching for 90 s and immediately transferred to a glass Petri dish filled with deionized water. The stannous selenide sulfide nanosheet/PMMA film was carefully lifted with a tweezer and cleaned three times with deionized water. The stannous selenide sulfide nanosheet/PMMA film was transferred to the GaAs substrate, such that the stannous selenide sulfide nanosheet was in contact with the GaAs window, and an overlapping part of the two formed a van der Waals heterojunction. Then, the PMMA film was softened by heating in hot acetone at 70° C. for 7 min, and immersed in a new acetone solution for 15 min to dissolve PMMA, obtaining a clean stannous selenide sulfide nanosheet/GaAs heterojunction.

Step 5. A 60 nm Au electrode was prepared on the stannous selenide sulfide nanosheet/GaAs heterojunction with a maskless UV lithography system and a thermal evaporation machine, and then annealed at 200° C. for 30 min under argon to remove small molecular impurities between the electrode and semiconductor materials to reduce the contact barrier, obtaining a photodiode based on lateral stannous selenide sulfide/GaAs heterojunction.

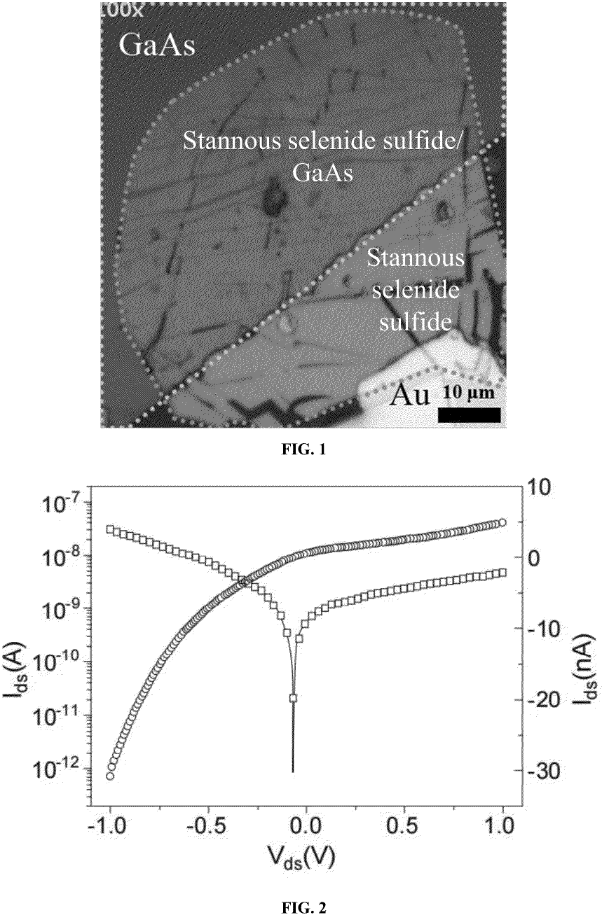

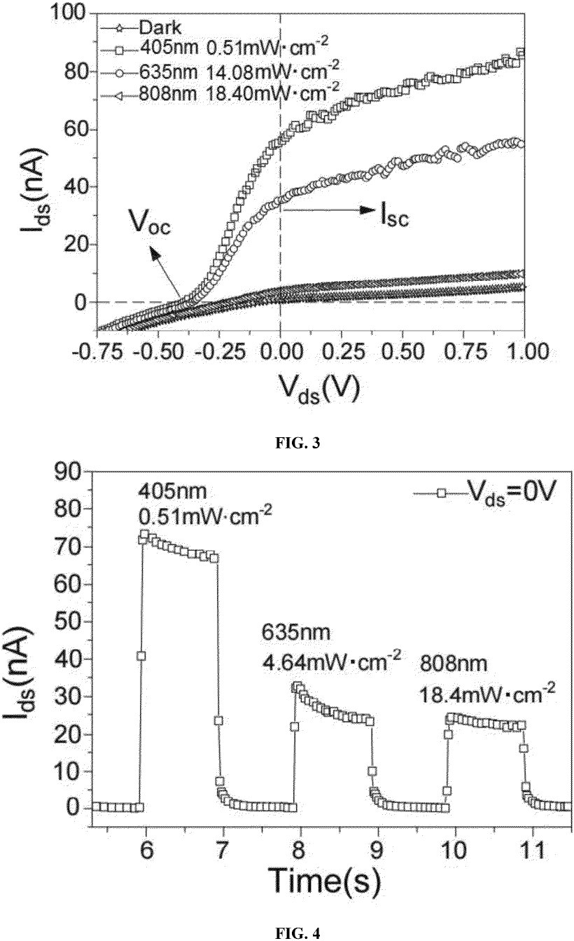

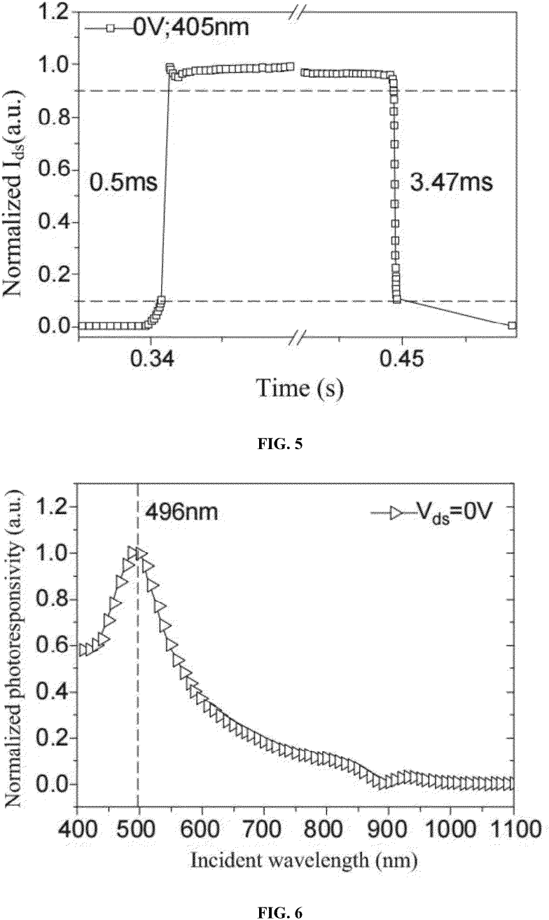

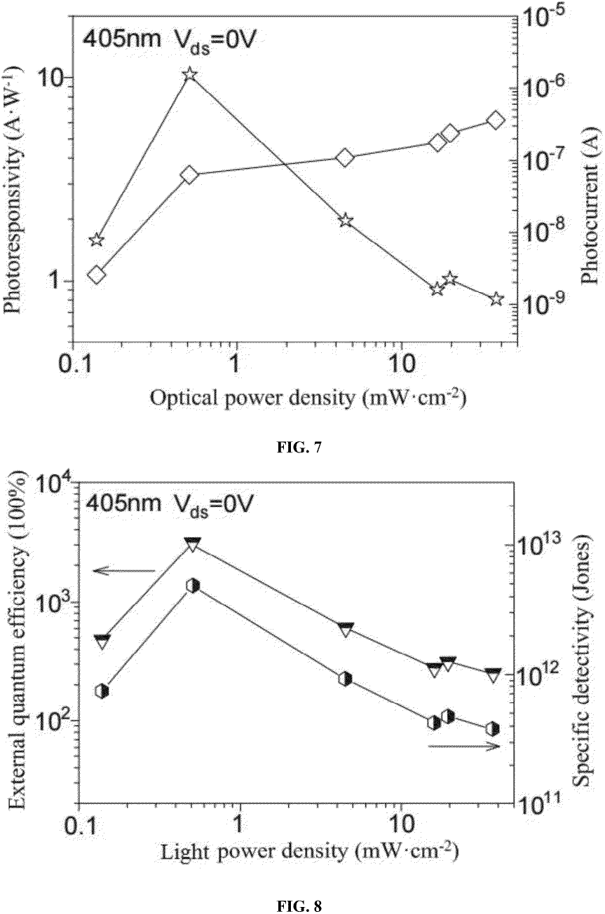

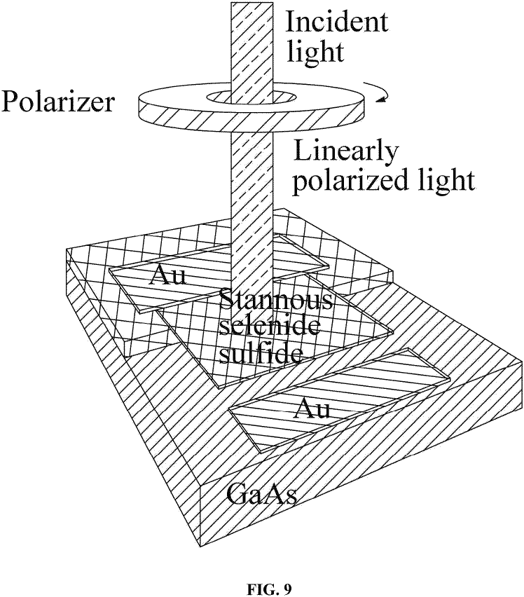

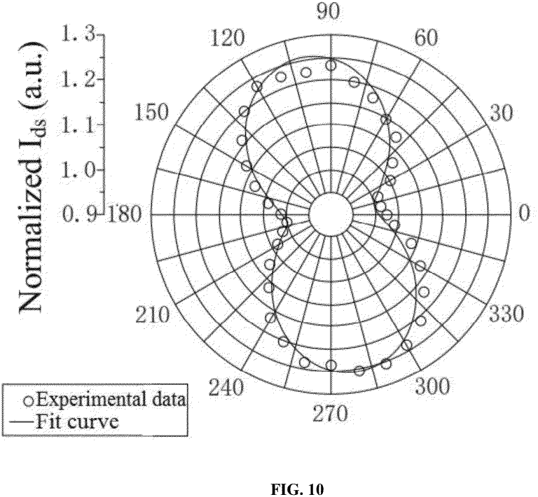

FIG. 1 is an optical microscope image of the stannous selenide sulfide nanosheet/GaAs heterojunction prepared according to Example 1. In the selected stannous selenide sulfide, a mass ratio of sulfur to selenium was 1:1. It can be seen from FIG. 1 that part of the stannous selenide sulfide nanosheets overlaps and GaAs to form a stannous selenide sulfide nanosheet/GaAs heterojunction, and an Au electrode is located on the stannous sulfide selenide nanosheets/ SiO₂ and GaAs separately. FIG. 2 is a current-voltage graph of the photodiode based on the lateral stannous selenide sulfide nanosheet/GaAs heterojunction of Example 1. In which, an anode is connected to stannous selenide sulfide, and a cathode is connected to GaAs. It is known from the test results that a ratio of a current with a bias voltage of -1 V to a current with a bias voltage of 1 V of the heterojunction is about 6, indicating that the photodiode based on the P-N stannous selenide sulfide/GaAs heterojunction has certain rectification behavior. FIG. 3 is a current-voltage graph of the photodiode based on the lateral stannous selenide sulfide nanosheet/GaAs heterojunction of Example 1 at different incident wavelengths. It can be seen from FIG. 3 that the photodiode based on the lateral stannous selenide sulfide nanosheet/GaAs heterojunction has both photoelectric effects and photovoltaic effects under irradiations of 405 nm, 635 nm and 808 nm incident light. Under the irradiation of the 405 nm incident light, the open-circuit voltage (V_{oc}) and short-circuit current (I_{sc}) reach 0.38 V and 55 nA separately, indicating that the photodiode based on the heterojunction has a large built-in electric field and excellent interfacial contact quality, and the photodiode based on the lateral stannous selenide sulfide nanosheet/GaAs heterojunction exhibits excellent photovoltaic properties. FIG. 4 is a current-time graph of the photodiode based on the lateral stannous selenide sulfide nanosheet/GaAs heterojunction of Example 1 at different wavelengths. It can be seen from FIG. 4 that the photodiode based on the lateral stannous selenide sulfide nanosheet/GaAs heterojunction exhibits stable and repeatable on-state and off-state current changes at different incident wavelengths, and has excellent multi-wavelength-responsive light switching characteristics. FIG. 5 is a graph showing the self-driven response time of the photodiode based on the lateral stannous selenide sulfide nanosheet/GaAs heterojunction of Example 1 under 405 nm laser light. It can be seen from FIG. 5 that the rise time and fall time of the photodiode based on the lateral stannous selenide sulfide nanosheet/GaAs heterojunction at an incident wavelength of 405 nm are 0.5 ms and 3.47 ms separately, indicating that under the action of the type-II band alignment and the built-in electric field, the photogenerated carriers can be rapidly separated, and the shallower energy level defect of stannous selenide sulfide also plays an important role in shortening the response time. FIG. 6 is a graph showing the normalized photoresponsivity of the photodiode based on the lateral stannous selenide sulfide nanosheet/GaAs heterojunction of Example 1 at different incident wavelengths and a bias voltage of 0 V. It can be seen from FIG. 6 that the photodiode based on the lateral stannous selenide sulfide nanosheet/GaAs heterojunction generates a certain photocurrent for 400-1,100 under the bias voltage of 0 V. In which, the normalized photoresponsivity reaches the maximum at an incident wavelength of 496 nm, which is the optimal absorption wavelength of the photodiode based on the lateral stannous selenide sulfide nanosheet/GaAs heterojunction. By adjusting the mass ratio of sulfur to selenium, the optimal absorption wavelength position and response time of the photodiode based on the lateral stannous selenide sulfide nanosheet/GaAs heterojunction can be controlled. FIG. 7 is a graph showing the relationship between the photoresponsivity-photocurrent and light power density of the photodiode based on the lateral stannous selenide sulfide nanosheet/GaAs heterojunction of Example 1 under 405 nm incident light and a bias voltage of 0 V. It can be seen from FIG. 7 that with the increasing optical power density, the photoresponsivity first increases and then decreases. At 0.51 mW·cm⁻², the photoresponsivity reaches the maximum value of 10.2 A·W⁻¹. FIG. 8 is a graph showing the relationship between the external quantum efficiency-specific detectivity and the light power density of the photodiode based on the lateral stannous selenide sulfide nanosheet/GaAs heterojunction of Example 1 under 405 nm incident light and a bias voltage of 0 V. It can be seen from FIG. 8 that the changing trend of the external quantum efficiency and the specific detectivity of the photodiode based on the lateral stannous selenide sulfide nanosheet/GaAs heterojunction with the light power density is the same as that of the photoresponsivity with the light power density. The maximum external quantum efficiency and specific detectivity reach 3,000% and 4.8×10¹² Jones, respectively. FIG. 9 is a schematic diagram of a three-dimensional structure of the photodiode based on the lateral stannous selenide sulfide nanosheet/GaAs heterojunction of Example 1 under irradiation of polarized light. FIG. 10 is a normalized photocurrent-angle polar plot of the photodiode based on the lateral stannous selenide sulfide nanosheet/GaAs heterojunction of Example 1 under 405 nm incident light. It can be seen from FIG. 9 and FIG. 10 that the photodiode based on the lateral stannous selenide sulfide nanosheet/GaAs heterojunction has a polarized photocurrent behavior of two-leaf shape under irradiation at 405 nm. The dichroic ratio reaches 1.25, and the angle of maximum photocurrent is 100°/280°. FIG. 11 is a normalized photocurrent-angle polar plot of the photodiode based on the lateral stannous selenide sulfide nanosheet/GaAs heterojunction of Example 1 under 635 nm incident light. It can be seen from FIG. 11 that the photodiode based on the lateral stannous selenide sulfide nanosheet/GaAs heterojunction has a polarized photocurrent behavior of two-leaf shape under irradiation at 635 nm. The dichroic ratio is enhanced to 1.45, and the angle of maximum photocurrent is changed, which is located at 60°/240°. It shows that the optimal absorption direction of the photodiode based on the lateral stannous selenide sulfide nanosheet/GaAs heterojunction is related to the incident wavelength, which has a certain relationship with the lattice orientation of stannous sulfide and stannous selenide components in the alloy and the changing trend of the incident wavelength.

### Example 2

The difference from Example 1 is that in step 3, the precursor was prepared by mixing stannous sulfide and stannous selenide powders in a mass ratio of 1:3. It should be noted that due to the lower equilibrium vapor pressure of stannous selenide, selenium in the obtained stannous selenide sulfide nanosheet had a relatively high content. Therefore, the mass of stannous selenide could be reduced as appropriate.

### Example 3

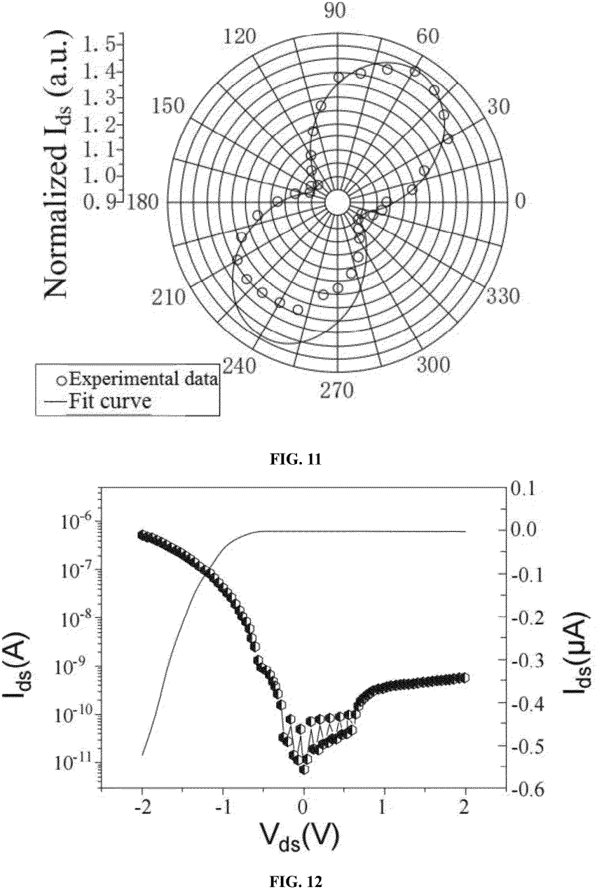

The difference from Example 1 is that in step 5, the Au electrodes were formed through thermal vapor deposition. In addition to preparing a 60 nm Au electrode on the surface of the stannous selenide sulfide nanosheet/GaAs heterojunction, a 100 nm Au film was also formed through thermal vapor deposition on a back of the GaAs. Then the sample was bonded to a copper sheet through a silver paste, and heated at 80° C. for 20 min on a heating plate, obtaining a photodiode based on a vertical stannous selenide sulfide nanosheet/GaAs heterojunction. Source and drain probes were respectively tied on the stannous selenide sulfide nanosheet and the copper sheet to test the vertical current. FIG. 12 is a current-voltage curve of the photodiode based on a vertical stannous selenide sulfide nanosheet/GaAs heterojunction of Example 3. It can be seen from FIG. 12 that the rectification ratio of the photodiode based on a vertical stannous selenide sulfide nanosheet/GaAs heterojunction can reach 10³, indicating that there is an excellent built-in potential and contact between the stannous selenide sulfide nanosheet and GaAs. In Example 1, the electrodes of the lateral (horizontal) heterojunction photodiode were all on the surface of the stannous selenide sulfide nanosheet, and the lateral current of the stannous selenide sulfide nanosheet/GaAs heterojunction was tested. While in the vertical heterojunction photodiode in the present example, one electrode was on the surface nanosheet of the stannous selenide sulfide nanosheet, the other electrode was on a back electrode of GaAs, and the vertical current of the stannous selenide sulfide nanosheet/GaAs heterojunction was tested.

### Example 4

The difference from Example 1 is that in step 4, when the stannous selenide sulfide nanosheet was transferred to the GaAs substrate, the stannous selenide sulfide nanosheet was spin-coated with a polystyrene (PS) toluene solution with a mass fraction of 9% at a high speed of 3,000 rpm for 1 min. Then the spin-coated product was heated on a heating plate at 90° C. for 20 min to form a PS film. The PS film was immersed in a glass petri dish filled with deionized water. The edge was carefully scraped with a sharp-nose tweezer and the film was slowly lifted, obtaining a stannous selenide sulfide nanosheet/PS film. After aligning the stannous selenide sulfide nanosheet/PS film with the GaAs window through an optical microscope, the GaAs substrate was continuously heated at 90° C. to make the PS film fully contact with the GaAs substrate, and finally immersed in a toluene solvent for 1-12 h, obtaining the stannous selenide sulfide nanosheet/GaAs heterojunction.

In the present disclosure, the photodiode includes a photodiode based on a lateral stannous selenide sulfide nanosheet/GaAs heterojunction and a photodiode based on a vertical stannous selenide sulfide nanosheet/GaAs heterojunction. In the photodiode based on a lateral stannous selenide sulfide nanosheet/GaAs heterojunction, the Au electrodes are formed through thermal vapor deposition on the stannous selenide sulfide nanosheet and a window of GaAs, respectively; in the photodiode based on a vertical stannous selenide sulfide nanosheet/ GaAs heterojunction, the Au electrodes are formed through thermal vapor deposition on the stannous selenide sulfide nanosheet and a back of GaAs, respectively. The Au electrode has a thickness of 20-500 nm. The protective gas is of nitrogen or argon. The annealing treatment is conducted for 15-120 min. The stannous selenide sulfide nanosheet has a lateral dimension of 10-100 µm and a thickness of 5-100 nm. In the present disclosure, the photodiode based on a stannous selenide sulfide nanosheet (an element mass ratio of sulfur to selenium is 1:1)/GaAs heterojunction has a wide spectral response (405-1,064 nm) and self-driven photoelectric performance (under 405 nm laser irradiation, its maximum photoresponsivity reaches 10.2 A·W⁻¹, the maximum specific detectivity reaches 4.8×10¹² Jones, and the rise and fall times are 0.5/3.47 ms). In addition, the stannous selenide sulfide nanosheet/GaAs heterojunction has dichroic ratios of 1.25 at 405 nm and 1.45 at 635 nm, and a remarkable polarized photocurrent can be obtained, which shows good potential for use in self-driven polarization-sensitive photodetectors at specific wavelengths.

The above examples are preferred embodiments of the present disclosure. However, the embodiments of the present disclosure are not limited by the above examples. Any change, modification, substitution, combination and simplification made without departing from the spiritual essence and principle of the present disclosure should be an equivalent replacement manner, and all are included in the protection scope of the present disclosure.

What is claimed is:

1. A photodiode based on a stannous selenide sulfide nanosheet/GaAs heterojunction, wherein the photodiode comprises a structure of the stannous selenide sulfide nanosheet/GaAs heterojunction, obtained by overlapping a stannous selenide sulfide nanosheet and GaAs, forming an Au electrodes through thermal vapor deposition on the stannous selenide sulfide nanosheet and GaAs, respectively, and conducting an annealing treatment in a protective gas at a temperature in a range of 150-250° C.

2. The photodiode according to claim 1, wherein the Au electrode has a thickness of 20-500 nm; the protective gas is nitrogen or argon; the annealing treatment is conducted for 15-120 min; the stannous selenide sulfide nanosheet has a lateral dimension of 10-100 µm and a thickness of 5-100 nm.

3. The photodiode according to claim 1, wherein the photodiode comprises a photodiode based on a lateral stannous selenide sulfide nanosheet/GaAs heterojunction and a photodiode based on a vertical stannous selenide sulfide nanosheet/GaAs heterojunction; in the photodiode based on a lateral stannous selenide sulfide nanosheet/GaAs heterojunction, the Au electrodes are formed through thermal vapor deposition on the stannous selenide sulfide nanosheet and a window of GaAs, respectively; in the photodiode based on a vertical stannous selenide sulfide nanosheet/ GaAs heterojunction, the Au electrodes are formed through thermal vapor deposition on the stannous selenide sulfide nanosheet and a back of GaAs, respectively.

4. A method for preparing the photodiode based on a stannous selenide sulfide nanosheet/ GaAs heterojunction according to claim 1, comprising:
S1, cleaning an N-type GaAs substrate with acetone, isopropanol and deionized water in sequence and drying with a nitrogen gun, and depositing a medium layer film on the N-type GaAs substrate by atomic layer deposition or plasma enhanced chemical thermal vapor deposition;
S2, photoetching and developing a window on the medium layer film by using ultraviolet lithography, and placing in an etchant to completely etch an exposed medium layer window to obtain a GaAs window;
S3, spin-coating a surface of a stannous selenide sulfide nanosheet/substrate with a soluble polymer solution, and heating and solidifying at a temperature in a range of 100-150° C. to obtain a polymer film/stannous selenide sulfide nanosheet/substrate;
S4, immersing the polymer film/stannous selenide sulfide nanosheet/substrate in a treatment solution, then aligning the polymer film/stannous selenide sulfide nanosheet separated from the substrate with the GaAs window obtained in step S2, and heating at a temperature in a range of 100-150° C. to make the stannous selenide sulfide nanosheet contact with the GaAs window to form a van der Waals heterojunction, so as to obtain a polymer film/stannous selenide sulfide nanosheet/GaAs substrate; and
S5, heating the polymer film/stannous selenide sulfide nanosheet/GaAs substrate in acetone at 70° C., then transferring to a fresh acetone solution for immersion, and cleaning to remove the polymer film; forming Au electrodes through thermal vapor deposition on the stannous selenide sulfide nanosheet and the GaAs window, respectively, and then conducting an annealing treatment in a protective gas at a temperature in a range of 150-250° C. to obtain the photodiode based on a stannous selenide sulfide nanosheet/GaAs heterojunction.

5. The method according to claim 4, wherein in step S1, the medium layer film is of SiO₂, Al₂O₃ or HfO₂, and has a thickness of 12-300 nm.

6. The method according to claim 4, wherein in step S2, the etchant comprises an aqueous hydrofluoric acid solution and an aqueous ammonium fluoride solution; a volume ratio of the aqueous hydrofluoric acid solution to the aqueous ammonium fluoride solution is in a range of (1-4):(6-24); a volume concentration of the aqueous hydrofluoric acid solution is in a range of 40-49%, and a volume concentration of the aqueous ammonium fluoride solution is in a range of 30-40%.

7. The method according to claim 4, wherein in step S3, the stannous selenide sulfide nanosheet has a lateral dimension of 10-100 µm and a thickness of 5-100 nm; the substrate is of SiO₂/Si, mica or sapphire.

8. The method according to claim 4, wherein in step S3, the soluble polymer solution is an anisole solution of polymethyl methacrylate or a toluene solution of polystyrene with a mass percentage of 8-10 wt.%; the spin-coating is conducted at a speed in a range of 3,000-7,000 rpm for 30-120 s; the heating is conducted for 15-45 min.

9. The method according to claim 4, wherein in step S4, the heating is conducted for 5-20 min; in step S5, the heating is conducted for 7-15 min, the immersion is conducted for 10 min-12 h, and the cleaning is conducted with solvents of isopropanol, anhydrous ethanol and deionized water successively.

10. A method for using the photodiode based on a stannous selenide sulfide nanosheet/GaAs heterojunction according to claim 1, wherein the photodiode based on a stannous selenide sulfide nanosheet/GaAs heterojunction is used in the field of photovoltaic devices or self -driven polarization-sensitive photodetectors.

11. The method according to claim 4, wherein the Au electrode has a thickness of 20-500 nm; the protective gas is nitrogen or argon; the annealing treatment is conducted for 15-120 min; the stannous selenide sulfide nanosheet has a lateral dimension of 10-100 µm and a thickness of 5-100 nm.

12. The method according to claim 4, wherein the photodiode comprises a photodiode based on a lateral stannous selenide sulfide nanosheet/GaAs heterojunction and a photodiode based on a vertical stannous selenide sulfide nanosheet/GaAs heterojunction; in the photodiode based on a lateral stannous selenide sulfide nanosheet/GaAs heterojunction, the Au electrodes are formed through thermal vapor deposition on the stannous selenide sulfide nanosheet and a window of GaAs, respectively; in the photodiode based on a vertical stannous selenide sulfide nanosheet/ GaAs heterojunction, the Au electrodes are formed through thermal vapor deposition on the stannous selenide sulfide nanosheet and a back of GaAs, respectively.

13. The method according to claim 10, wherein the Au electrode has a thickness of 20-500 nm; the protective gas is nitrogen or argon; the annealing treatment is conducted for 15-120 min; the stannous selenide sulfide nanosheet has a lateral dimension of 10-100 µm and a thickness of 5-100 nm.

14. The method according to claim 10, wherein the photodiode comprises a photodiode based on a lateral stannous selenide sulfide nanosheet/GaAs heterojunction and a photodiode based on a vertical stannous selenide sulfide nanosheet/GaAs heterojunction; in the photodiode based on a lateral stannous selenide sulfide nanosheet/GaAs heterojunction, the Au electrodes are formed through thermal vapor deposition on the stannous selenide sulfide nanosheet and a window of GaAs, respectively; in the photodiode based on a vertical stannous selenide sulfide nanosheet/ GaAs heterojunction, the Au electrodes are formed through thermal vapor deposition on the stannous selenide sulfide nanosheet and a back of GaAs, respectively.
